(19) United States
(12) Patent Application Publication
(10) Pub. No.: US 2026/0143962 A1
(43) Pub. Date: May 21, 2026

(54) PLATINUM COMPLEX LUMINESCENT MATERIAL AND DEVICE CONTAINING THE SAME

(71) Applicant: GUANGDONG AGLAIA OPTOELECTRONIC MATERIALS CO. LTD, Foshan (CN)

(72) Inventors: Huiyang Li, Foshan (CN); Xinwei Wu, Foshan (CN); Lei Dai, Foshan (CN); Lifei Cai, Foshan (CN)

(21) Appl. No.: 18/704,164

(22) PCT Filed: Oct. 4, 2022
(86) PCT No.: PCT/CN2022/123699

§ 371 Date: Apr. 24, 2024

(30) Foreign Application Priority Data
Nov. 1, 2021 (CN) 202111282434.1

(51) Int. Cl. H10K 85/30; C07F 15/00; C09K 11/06; H10K 50/12

(52) U.S. Cl. CPC H10K 85/346; C07F 15/0086; C09K 11/06; C09K 2211/1007; C09K 2211/1029; C09K 2211/1033; C09K 2211/1037; C09K 2211/1044; C09K 2211/185; H10K 50/12

(57) ABSTRACT

The present application relates to a platinum complex luminescent material. The platinum complex is a compound having the structure represented by chemical formula (I) The present application also provides an organic electroluminescent device, including a cathode, an anode and an organic layer. The organic layer includes one or more of a hole injection layer, a hole transport layer, a light-emitting layer, a hole blocking layer, an electron transport layer, or an electron injection layer. At least one layer of the organic layer contains the compound represented by formula (I).

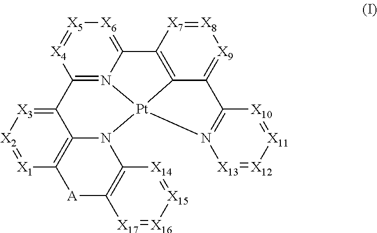

### TECHNICAL FIELD

The present application relates to the field of luminescent materials, in particular to a NNCN tetradentate ligand-containing platinum complex and a use thereof in an organic light-emitting diode.

### BACKGROUND

The organic photoelectronic device includes, but is not limited to, the organic light-emitting diode (OLED), the organic thin film transistor (OTFT), the organic photovoltaic device (OPV), the luminescent electrochemical cell (LCE), and the chemical sensor.

In recent years, the OLED, as a lighting and display technology with great application prospect, has received extensive attentions from both academia and industry. The OLED device, which has the characteristics such as self-luminescence, wide viewing angle, short response time, and the ability to prepare flexible devices, is a strong contender for the next generation of display and lighting technology. However, currently, the OLED still has problems such as low efficiency and short lifetime and thus needs to be further researched.

In the early fluorescent OLED, typically only the singlet state is utilized to emit lights, and the triplet excitons produced in the device cannot be effectively utilized and return to the ground state by non-radiative means, limiting the widespread use of the OLED. The phenomenon of electrophosphorescence was first reported by Zhiming Zhi, et al. at the University of Hong Kong in 1998. In the same year, a phosphorescent OLED was prepared by Thompson et al. with a transition metal complex as a luminescent material. The phosphorescent OLED can efficiently utilize singlet and triplet excitons to emit lights, with a theoretical internal quantum efficiency of 100%, greatly promoting the commercialization of the OLED. The color of the lights emitted by the OLED can be regulated by the structural design of the luminescent material. The OLED may include one or more light-emitting layers to achieve the desired spectrum. At present, green, yellow, and red phosphorescent materials have been commercialized. The commercialized OLED display typically use the combination of blue fluorescence with the yellow or green phosphorescence and the red phosphorescence to achieve the full-color display. However, a luminescent material with a higher efficiency and a longer service life is urgently needed in the industry currently. The metal complex luminescent material has been applied in the industry, but the performances thereof, such as the luminous efficiency and the service life, still need to be further improved.

### SUMMARY

In view of the above-mentioned problems in the prior art, the present application provides a NNCN tetradentate ligand-containing platinum complex luminescent material, which exhibits a good luminous efficiency when applied to an organic light-emitting diode.

The present application further provides an organic light-emitting diode containing the platinum complex.

The NNCN tetradentate ligand-containing platinum complex is a compound having a structure of formula (I):

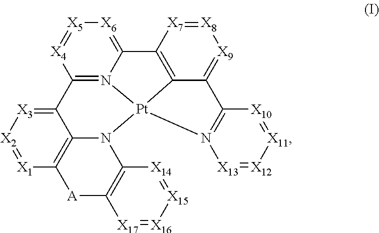

wherein,
X₁ to X₁₇ are each independently selected from the group consisting of N and CR; A is selected from the group consisting of CR¹R², NR³, O, S, and Se;
R, R¹, R², and R³ are each independently selected from the group consisting of hydrogen, deuterium, halogen, amino, carbonyl, carboxyl, thioalkyl, cyano, sulfonyl, phosphino, a substituted or unsubstituted alkyl having 1 to 20 carbon atoms, a substituted or unsubstituted cycloalkyl having 3 to 20 ring carbon atoms, a substituted or unsubstituted alkenyl having 2 to 20 carbon atoms, a substituted or unsubstituted alkoxy having 1 to 20 carbon atoms, a substituted or unsubstituted aryl having 6 to 30 carbon atoms, a substituted or unsubstituted heteroaryl having 3 to 30 carbon atoms, and a combination thereof; or any two adjacent substituents can optionally be linked to form a ring;
a heteroatom in the heteroaryl includes one or more of N, S, or O;
the “substituted” refers to substitution with halogen, amino, cyano, or C1-C4 alkyl.

In an embodiment, R, R¹, R², and R³ are each independently selected from the group consisting of hydrogen, deuterium, halogen, amino, thioalkyl, cyano, a substituted or unsubstituted alkyl having 1 to 6 carbon atoms, a substituted or unsubstituted cycloalkyl having 3 to 6 ring carbon atoms, a substituted or unsubstituted alkenyl having 2 to 6 carbon atoms, a substituted or unsubstituted alkoxy having 1 to 6 carbon atoms, a substituted or unsubstituted aryl having 6 to 12 carbon atoms, and a substituted or unsubstituted heteroaryl having 3 to 6 carbon atoms.

In an embodiment, R, R¹, R², and R³ are each independently selected from the group consisting of hydrogen, deuterium, halogen, C1-C4 alkyl, cyano, a substituted or unsubstituted cycloalkyl having 3 to 6 ring carbon atoms, a substituted or unsubstituted aryl having 6 to 12 carbon atoms, and a substituted or unsubstituted heteroaryl having 3 to 6 carbon atoms.

In an embodiment, R, R¹, R², and R³ are each independently selected from the group consisting of hydrogen, deuterium, methyl, isopropyl, isobutyl, tert-butyl, cyano, a substituted or unsubstituted cyclopentyl, a substituted or unsubstituted cyclohexyl, a substituted or unsubstituted phenyl, a substituted or unsubstituted pyridyl, a substituted or unsubstituted pyrazinyl, and a substituted or unsubstituted pyrimidinyl.

In an embodiment, the general formula (I) is of the following structure:

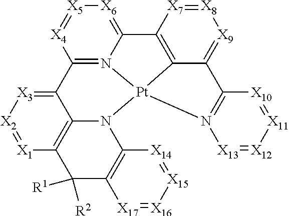

R, R¹, and R² are each independently selected from the group consisting of hydrogen, deuterium, methyl, tert-butyl, a substituted or unsubstituted cyclopentyl, a substituted or unsubstituted cyclohexyl, a substituted or unsubstituted phenyl, and a substituted or unsubstituted pyridyl.

In an embodiment, the general formula (I) is of the following structure:

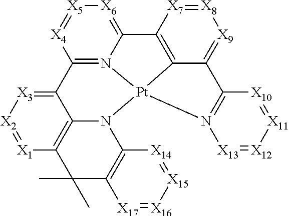

R is selected from the group consisting of hydrogen, deuterium, methyl, tert-butyl, a substituted or unsubstituted cyclopentyl, a substituted or unsubstituted cyclohexyl, a substituted or unsubstituted phenyl, and a substituted or unsubstituted pyridyl.

In an embodiment, X₁ to X₁₇ are each independently selected from CR.

In an embodiment, X₁ to X₃, and X₁₄ to X₁₇ are CH.

In an embodiment, at least one CR in X₄ to X₆ is not CH; at least one CR in X₇ to X₉ is not CH, and at least one CR in X₁₀ to X₁₃ is not CH.

In an embodiment, X₅ in X₄ to X₆ is not CH, X₈ in X₇ to X₉ is not CH, X₁₁ in X₁₀ to X₁₃ is not CH, while the rest are CH.

In an embodiment, at least one CR in X₄ to X₆ is not CH; X₇ to X₉ are CH, and at least one CR in X₁₀ to X₁₃ is not CH.

In an embodiment, X₅ in X₄ to X₆ is not CH, X₁₁ in X₁₀ to X₁₃ is not CH, and the rest are CH.

Examples of the platinum metal complex according to the present application are listed below. However, the platinum metal complex is not limited to the listed structures:

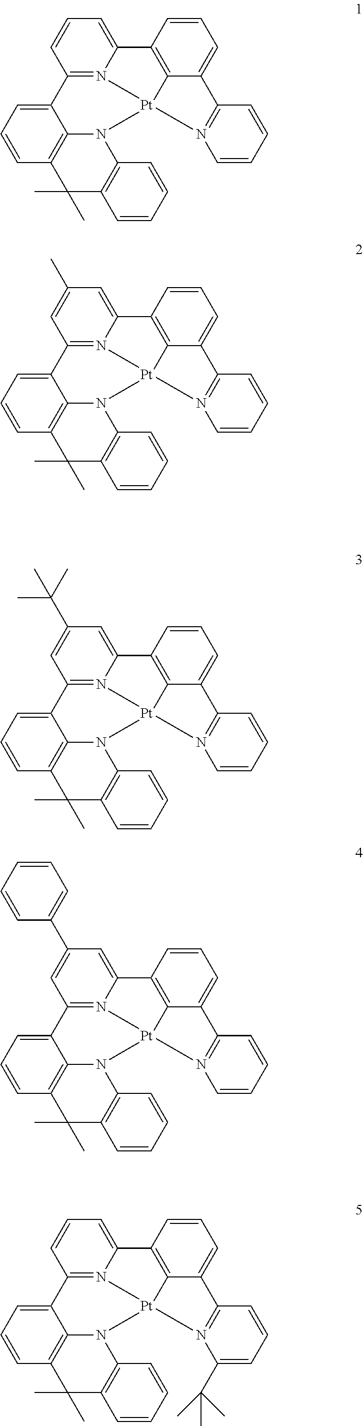

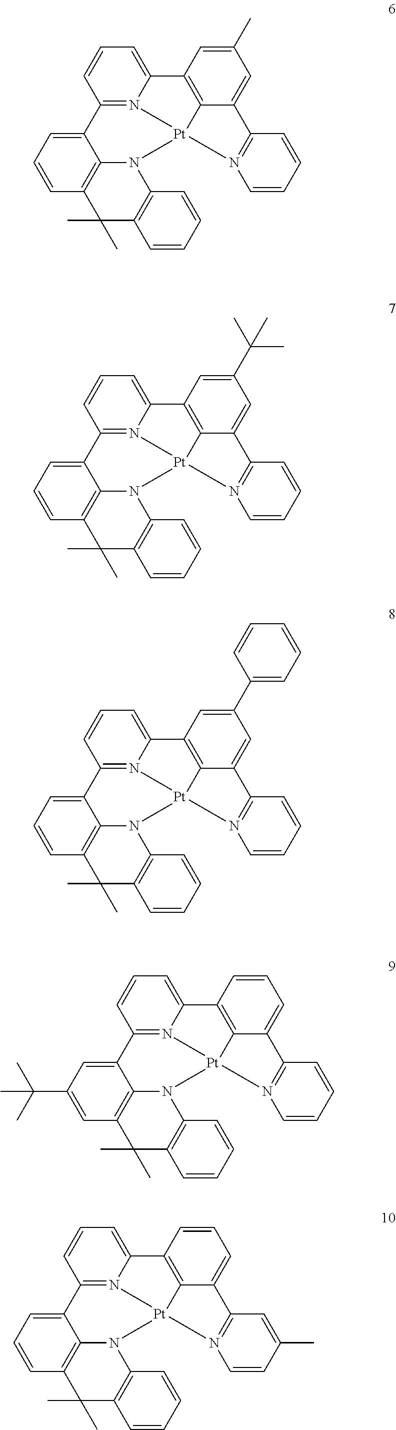

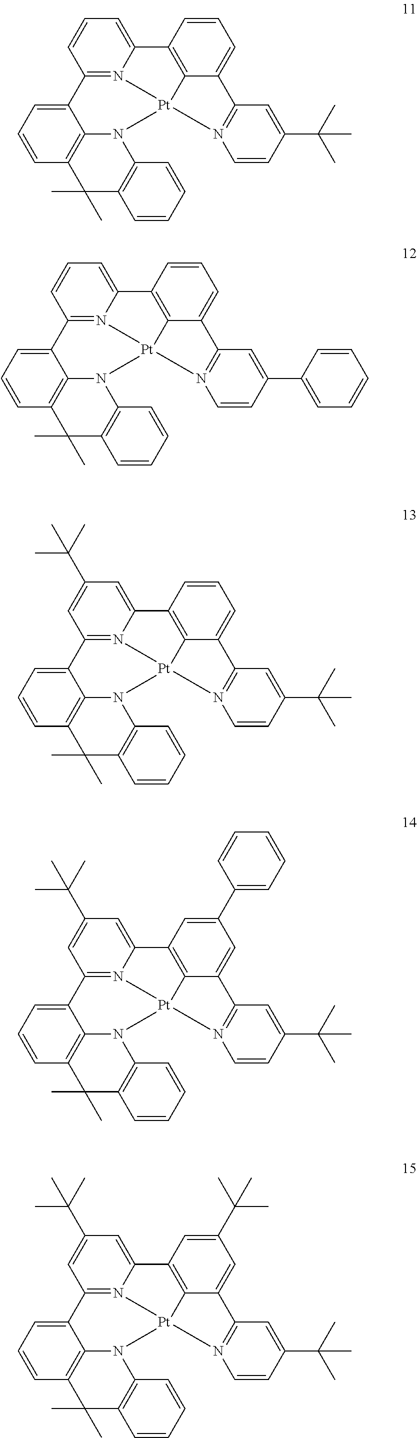

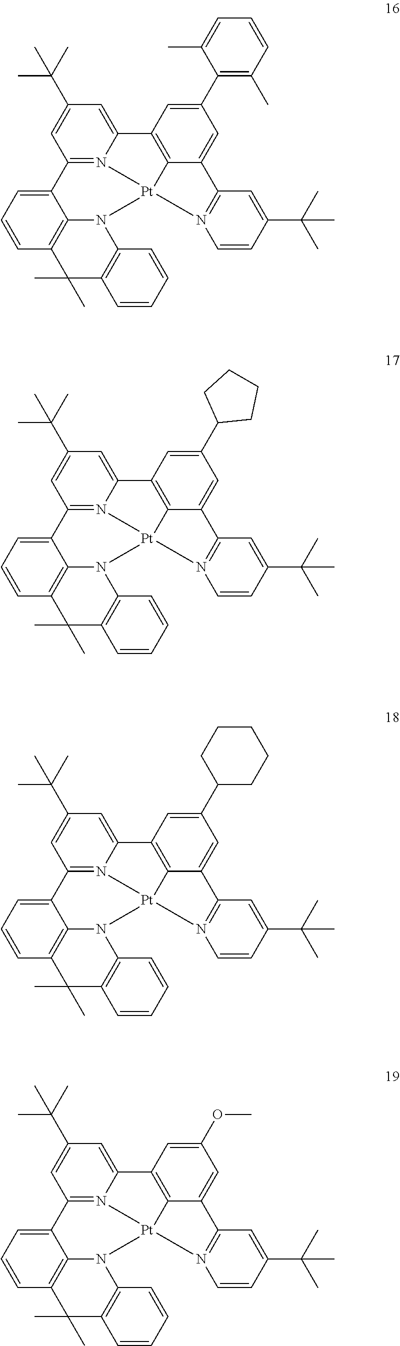

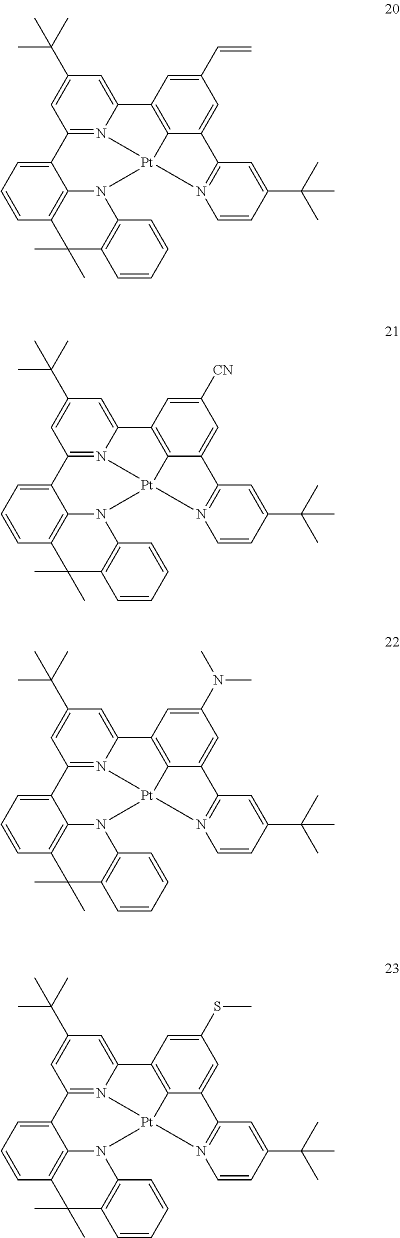

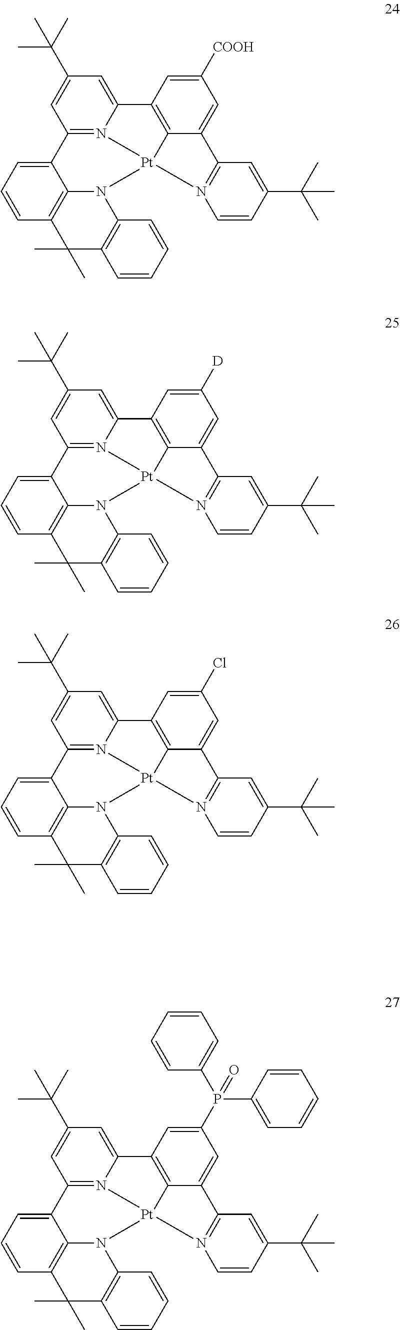

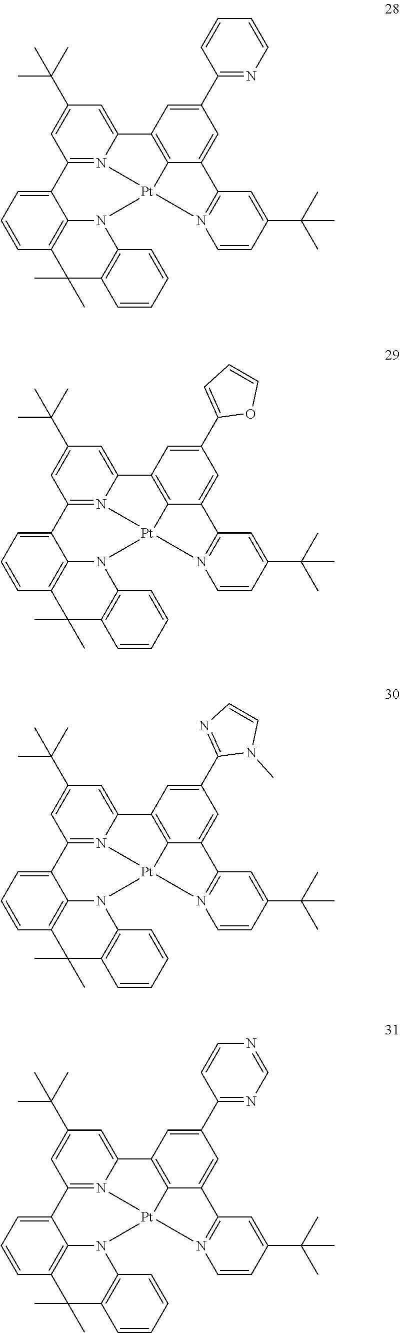

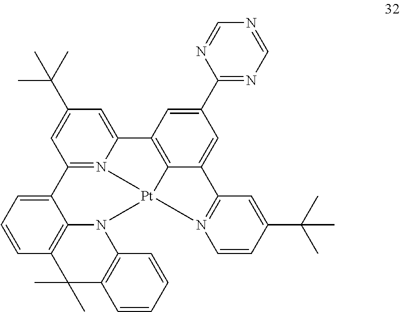

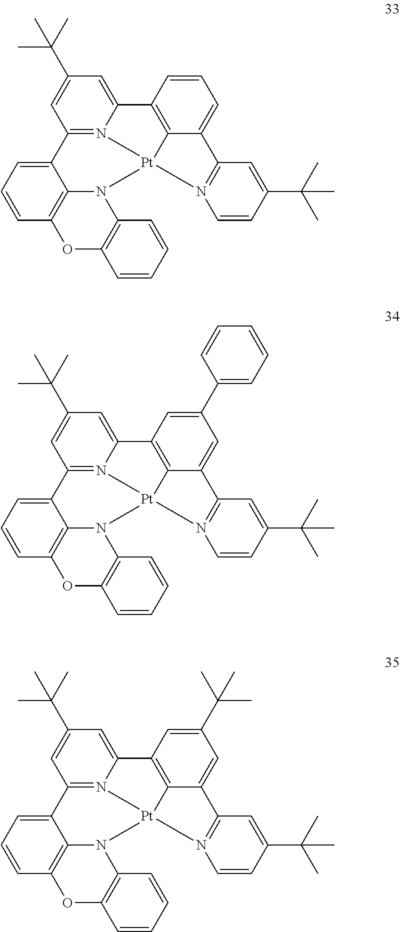

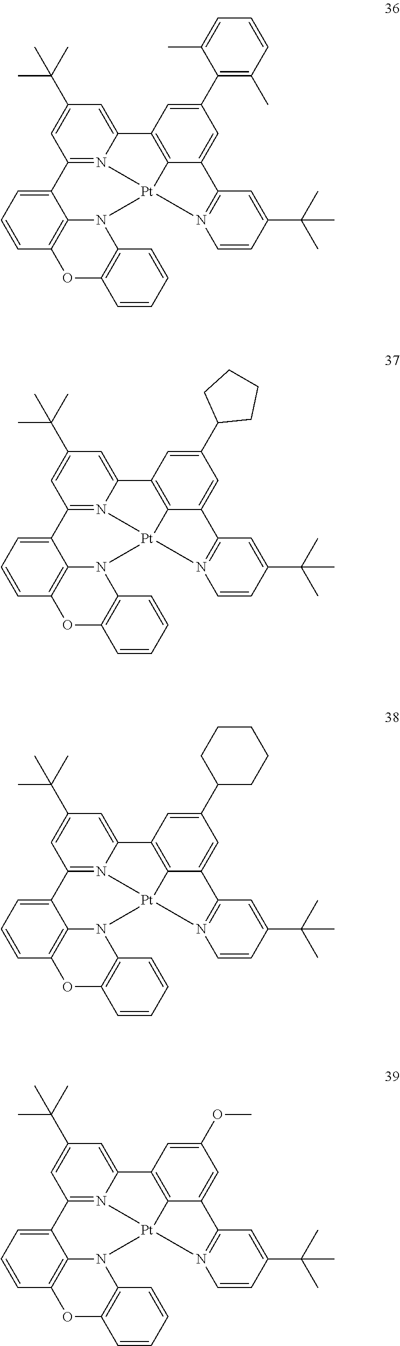

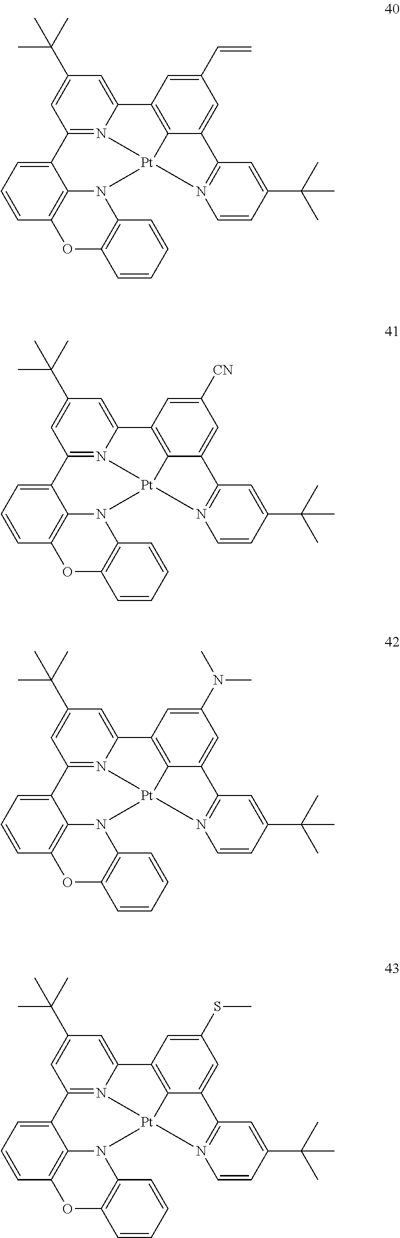

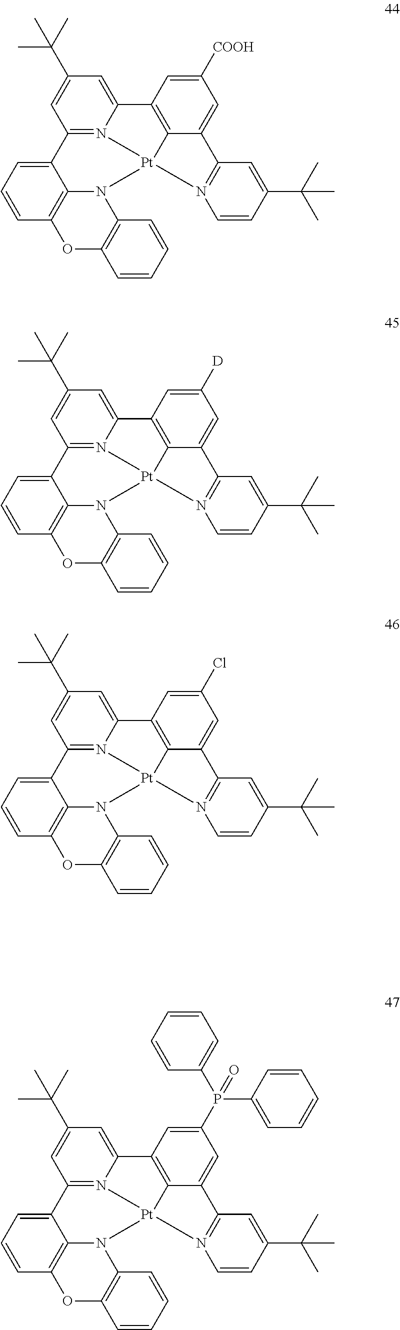

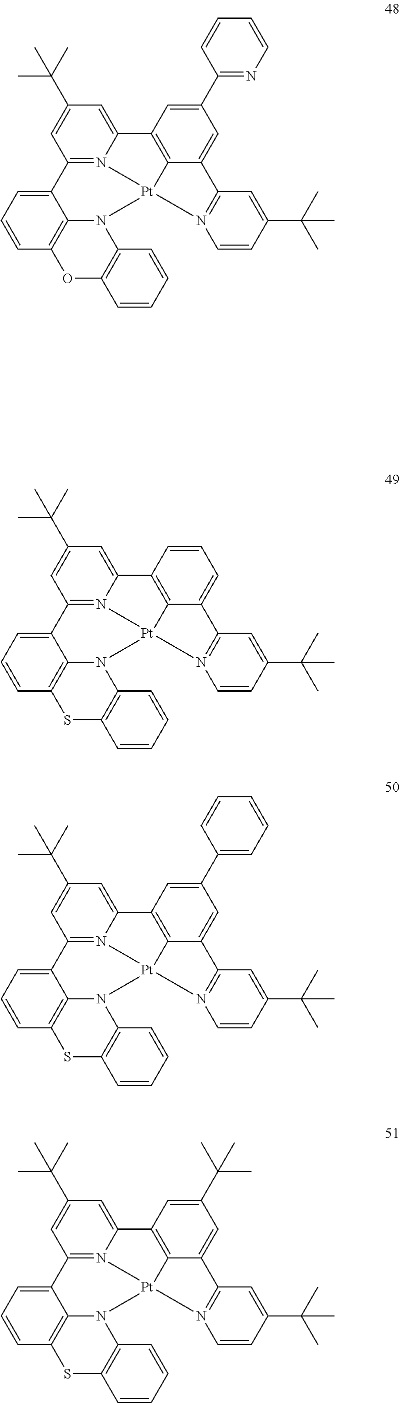

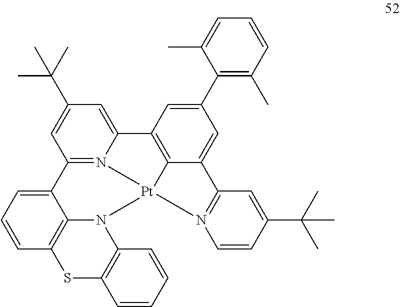

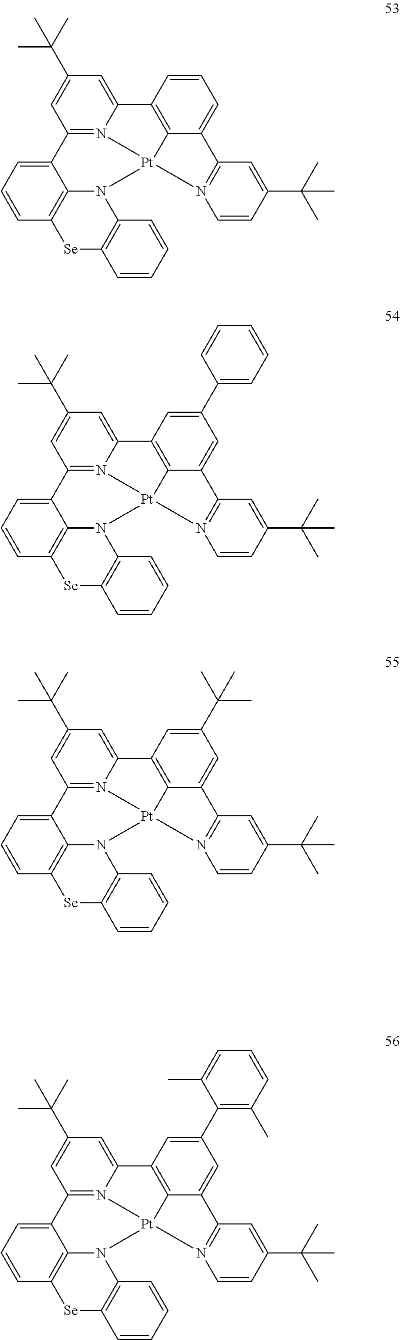

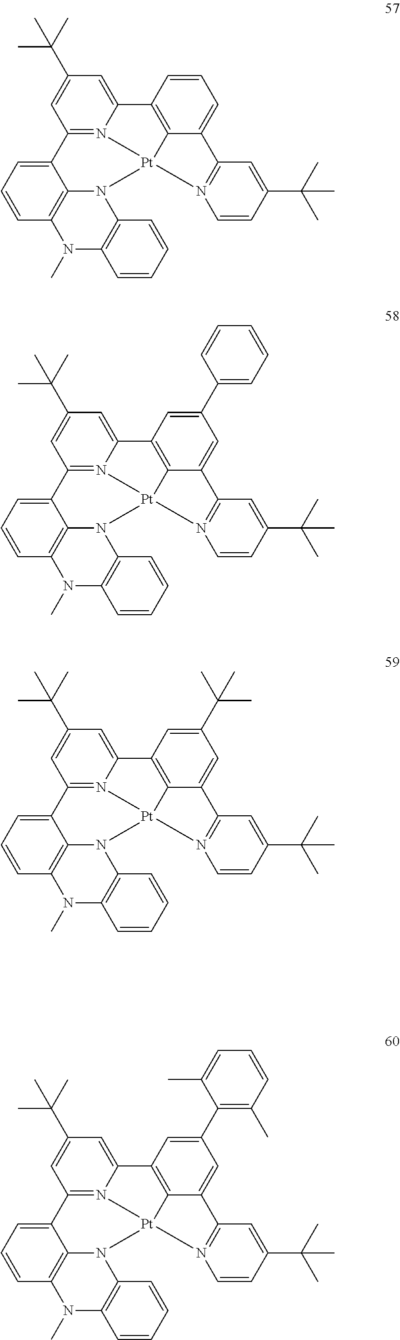

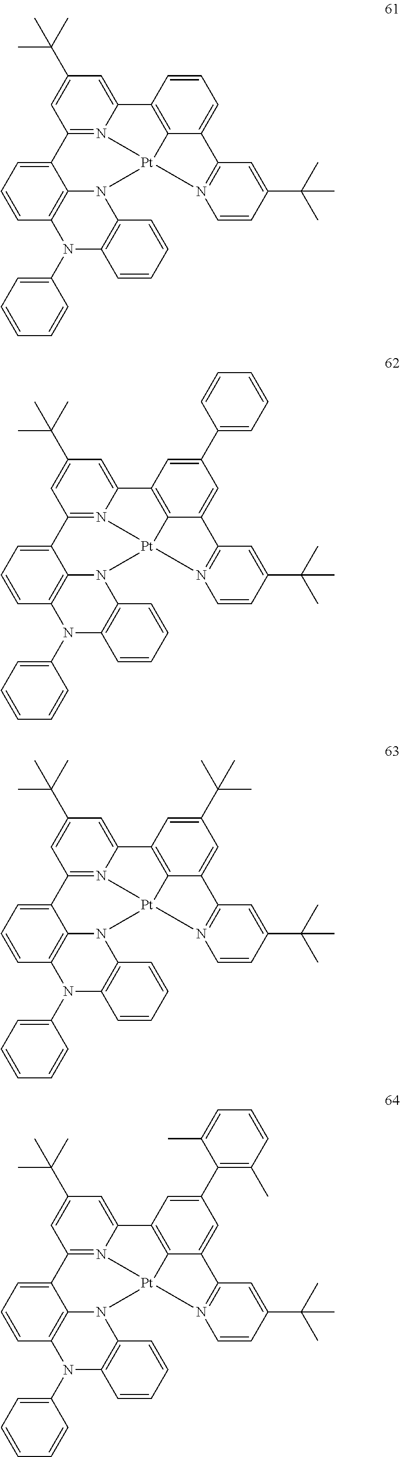

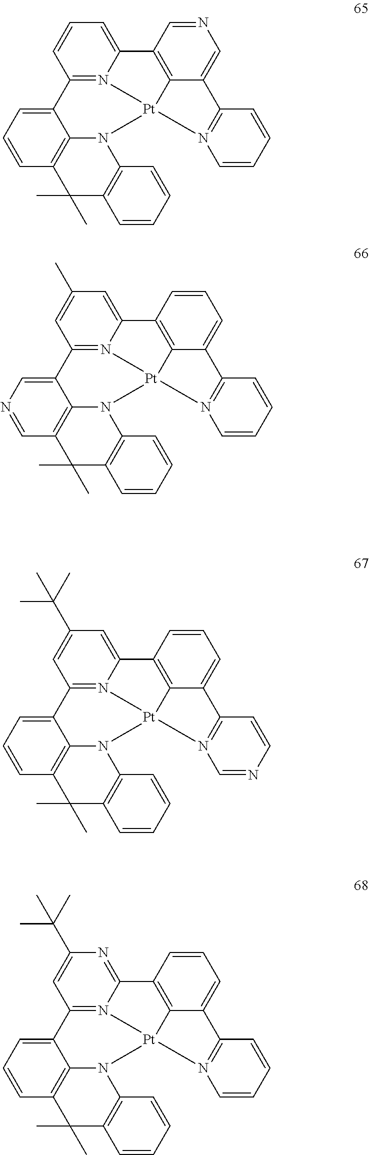

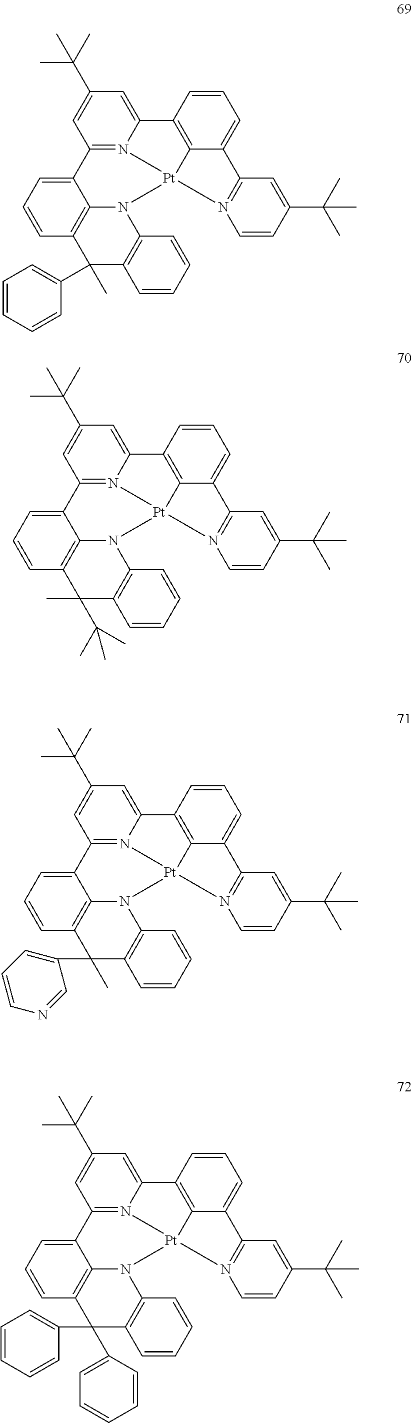

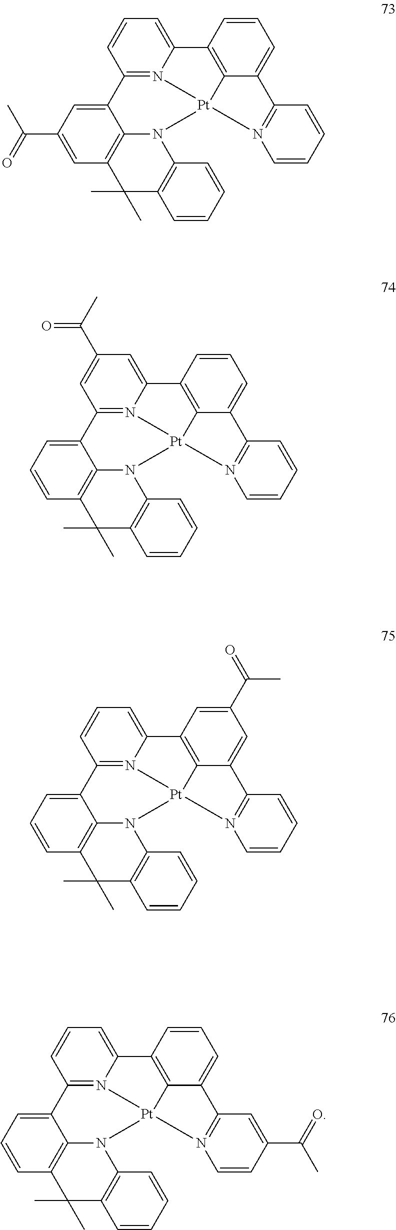

A precursor, i.e., a ligand, of the above-mentioned metal complex has the following structural formula:

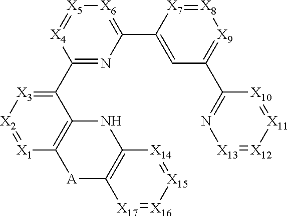

wherein X₁ to X₁₇ and A are as defined above.

The present application further provides a use of the above-mentioned platinum complex in an organic photoelectronic device. The photoelectronic device includes, but is not limited to, an organic light-emitting diode, an organic thin film transistor, an organic photovoltaic device, a luminescent electrochemical cell, and a chemical sensor, for example, an organic light-emitting diode.

An organic light-emitting diode including the above-mentioned platinum complex is provided, wherein the platinum complex is used as a luminescent material in the light-emitting device.

The organic light-emitting diode in the present application includes a cathode, an anode, and an organic layer. The organic layer includes one or more of a hole injection layer, a hole transport layer, a light-emitting layer, a hole blocking layer, an electron injection layer, or an electron transport layer, and it is not necessary for each of these organic layers to be present. At least one of the hole injection layer, the hole transport layer, the hole blocking layer, the electron injection layer, the light-emitting layer, or the electron transport layer includes the platinum complex of formula (I).

Preferably, the layer including the platinum complex of formula (I) is the light-emitting layer or the electron transport layer.

The organic layer in the device of the present application has a total thickness of 1 nm to 1000 nm, such as 1 nm to 500 nm, for example 5 nm to 300 nm.

The organic layer can be a thin film formed by an evaporation method or a solution method.

The present application discloses a series of platinum complex luminescent materials which has good luminescent property and can be applied in an organic light-emitting diode as a luminescent material, has a low driving voltage and a high luminous efficiencies and can significantly increase the service life of the device, and thus has potential to be applied in the field of organic electroluminescent devices.

### BRIEF DESCRIPTION OF THE DRAWINGS

FIG. 1 shows a structural diagram of an organic light-emitting diode device of the present application.

In the FIGURE, 10 denotes a glass substrate, 20 denotes an anode, 30 denotes a hole injection layer, 40 denotes a hole transport layer, 50 denotes a light-emitting layer, 60 denotes an electron transport layer, 70 denotes an electron injection layer, and 80 denotes a cathode.

### DETAILED DESCRIPTION OF THE EMBODIMENTS

There is no requirement on the methods for synthesizing the materials in the present application. In order to describe the present application in more detail, the following examples are provided, but the present application is not limited thereto. The raw materials used in the following synthesis processes are all commercially available products unless otherwise specified.

### Example 1: Synthesis of Complex 13

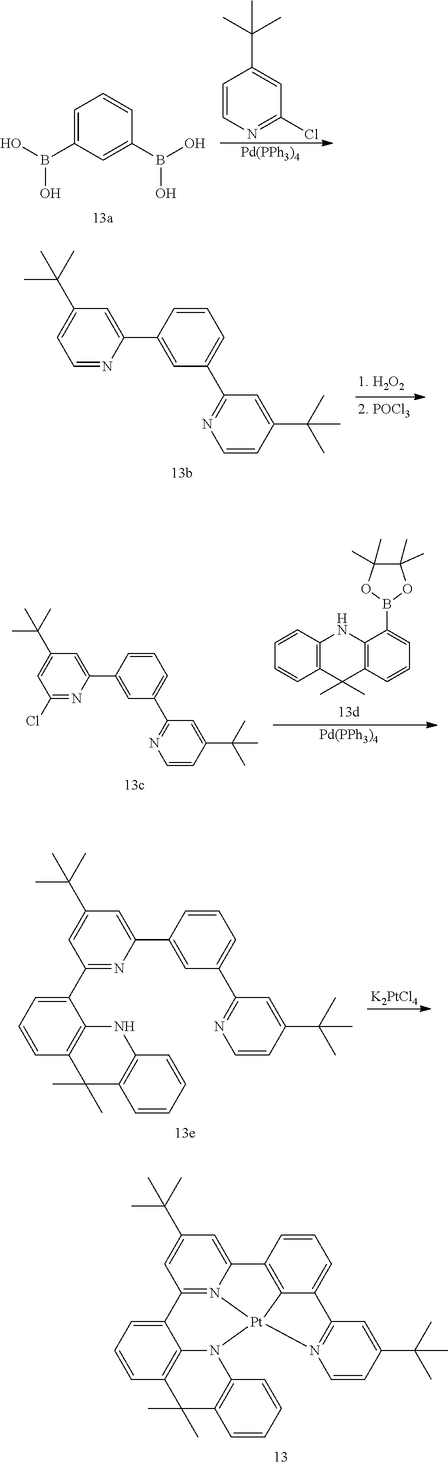

### Synthesis of Compound 13b

Isophthalic acid (4.0 g, 24.1 mmol), 4-tert-butyl-2-chloro-pyridine (9.0 g, 53.0 mmol), tetrakis(triphenylphosphine) palladium (1.39 g, 1.21 mmol), potassium carbonate solution (2M, 12 mL), and toluene (40 mL) were added to a three-necked flask under the protection of nitrogen. After repeating vacuuming and nitrogen introduction three times, the reaction mixture was heated to reflux and stirred overnight. After cooling to room temperature, the mixture was extracted with ethyl acetate. The organic phase was washed with a saturated saline solution for three times, dried over anhydrous sodium sulfate, and then subjected to an evaporation under reduced pressure to remove the solvent. The residue was subjected to a separation by silica gel column chromatography to obtain 6.2 g of a pale yellow oil product with a yield of 75%. ESI-MS (m z): 345.23 (M+1).

### Synthesis of Compound 13c

13b (4.0 g, 11.6 mmol), 30% hydrogen peroxide (2 mL), and acetic acid (20 mL) were added to the flask, stirred at room temperature for 30 minutes, and then heated to 60° C., at which a reaction was carried out for 6 hours under stirring. After cooling to room temperature, the mixture was extracted with ethyl acetate. The organic phase was washed with a saturated sodium sulfite solution for three times, dried over anhydrous sodium sulfate, and then subjected to an evaporation under reduced pressure to remove the solvent. The residual crude product was dissolved in phosphorus oxychloride (10 mL), heated to reflux, and stirred for 4 hours. After subjecting to an evaporation under reduced pressure to remove most of the phosphorus oxychloride, the mixture was slowly added into a saturated sodium carbonate solution. The mixture was extracted with dichloromethane. The organic phases were combined, dried over anhydrous sodium sulfate, and then subjected to an evaporation under reduced pressure to remove the solvent. The residue was subjected to a separation by silica gel column chromatography to obtain 2.1 g of a pale yellow solid with a yield of 48%. ESI-MS (m z): 379.19 (M+1).

### Synthesis of Compound 13e

13c (1.8 g, 4.8 mmol), 13d (synthesized with reference to patent KR20200109533A, 1.6 g, 4.8 mmol), tetrakis(triphenylphosphine) palladium (0.28 g, 0.24 mmol), potassium carbonate solution (2M, 5 mL), and toluene (20 mL) were added to a three-necked flask under the protection of nitrogen. After repeating vacuuming and nitrogen introduction three times, the reaction mixture was heated to reflux and stirred overnight. After cooling to room temperature, the mixture was extracted with ethyl acetate. The organic phase was washed with a saturated saline solution for three times, dried over anhydrous sodium sulfate, and then subjected to an evaporation under reduced pressure to remove the solvent. The residue was subjected to a separation by silica gel column chromatography to obtain 1.6 g of a pale yellow solid with a yield of 61%. ESI-MS (m z): 552.33 (M+1).

### Synthesis of Complex 13

In a 250 mL of single-necked flask, 13e (0.90 g, 1.63 mmol), potassium tetrachloroplatinate (0.81 g, 1.95 mmol), and tetrabutylammonium bromide (50 mg) were dissolved in acetic acid (150 mL), and subjected to a rection under stirring and the protection of nitrogen at 135° C. for 24 hours. After cooling to room temperature, the reaction liquid was added with water to precipitate a solid, and filtered to obtain a crude product. The crude product was recrystallized in dichloromethane/n-hexane (1/1) to obtain 0.65 g of orange red powder with a yield of 54%. ESI-HRMS (m z): 745.2872 (M+1).

### Example 2: Synthesis of Complex 33

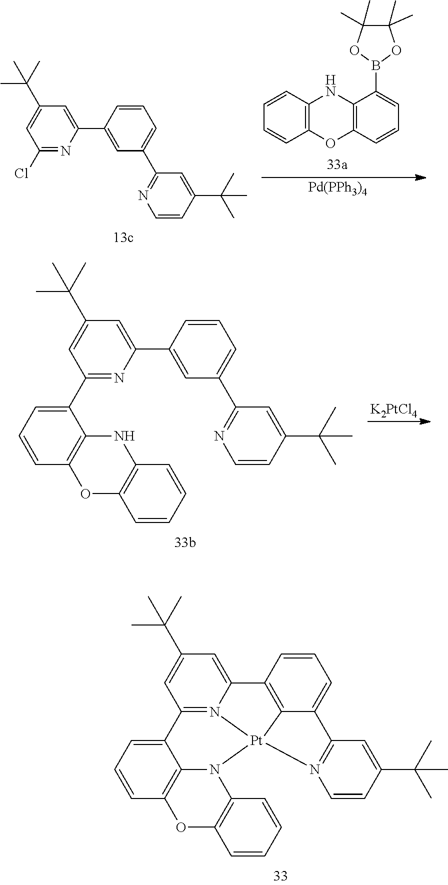

### Synthesis of Compound 33b

13c (1.2 g, 3.17 mmol), 33a (synthesized with reference to patent KR20200109533A, 0.98 g, 3.17 mmol), tetrakis(triphenylphosphine) palladium (0.18 g, 0.16 mmol), potassium carbonate solution (2M, 4 mL), and toluene (20 mL) were added to a three-necked flask under the protection of nitrogen. After repeating vacuuming and nitrogen introduction three times, the reaction mixture was heated to reflux and stirred overnight. After cooling to room temperature, the mixture was extracted with ethyl acetate. The organic phase was washed with a saturated saline solution for three times, dried over anhydrous sodium sulfate, and then subjected to an evaporation under reduced pressure to remove the solvent. The residue was subjected to a separation by silica gel column chromatography to obtain 1.2 g of a pale yellow solid with a yield of 72%. ESI-MS (m z): 526.28 (M+1).

### Synthesis of Complex 33

In a 250 mL of single-necked flask, 33b (0.90 g, 1.71 mmol), potassium tetrachloroplatinate (0.85 g, 2.05 mmol), and tetrabutylammonium bromide (50 mg) were dissolved in acetic acid (150 mL), and subjected to a rection under stirring and the protection of nitrogen at 135° C. for 24 hours. After cooling to room temperature, the reaction liquid was added with water to precipitate a solid, and filtered to obtain a crude product. The crude product was recrystallized in dichloromethane/n-hexane (1/1) to obtain 0.55 g of orange red powder with a yield of 45%. ESI-HRMS (m z): 719.2355 (M+1).

### Example 3: Synthesis of Complex 49

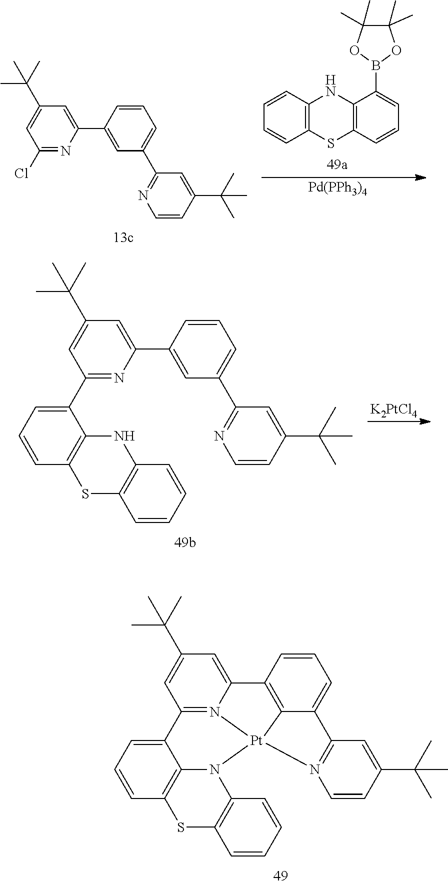

### Synthesis of Compound 49b

13c (1.20 g, 3.17 mmol), 49a (synthesized with reference to patent KR20200109533A, 1.24 g, 3.81 mmol), tetrakis(triphenylphosphine) palladium (0.18 g, 0.16 mmol), potassium carbonate solution (2M, 4 mL), and toluene (20 mL) were added to a three-necked flask under the protection of nitrogen. After repeating vacuuming and nitrogen introduction three times, the reaction mixture was heated to reflux and stirred overnight. After cooling to room temperature, the mixture was extracted with ethyl acetate. The organic phase was washed with a saturated saline solution for three times, dried over anhydrous sodium sulfate, and then subjected to an evaporation under reduced pressure to remove the solvent. The residue was subjected to a separation by silica gel column chromatography to obtain 1.1 g of a pale yellow solid with a yield of 64%. ESI-MS (m z): 542.26 (M+1).

### Synthesis of Complex 49

In a 250 mL of single-necked flask, 49b (0.95 g, 1.75 mmol), potassium tetrachloroplatinate (0.87 g, 2.10 mmol), and tetrabutylammonium bromide (50 mg) were dissolved in acetic acid (150 mL), and subjected to a rection under stirring and the protection of nitrogen at 135° C. for 24 hours. After cooling to room temperature, the reaction liquid was added with water to precipitate a solid, and filtered to obtain a crude product. The crude product was recrystallized in dichloromethane/n-hexane (1/1) to obtain 0.60 g of orange red powder with a yield of 47%. ESI-HRMS (m z): 735.2125 (M+1).

### Example 4: Synthesis of Complex 61

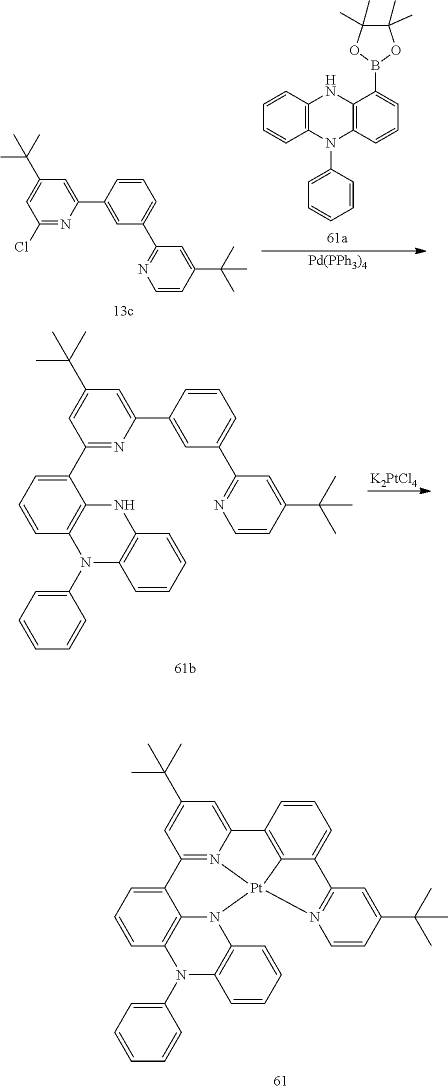

### Synthesis of Compound 61b

13c (1.10 g, 2.90 mmol), 61a (synthesized with reference to patent KR20200109533A, 1.34 g, 3.49 mmol), tetrakis(triphenylphosphine) palladium (0.17 g, 0.15 mmol), potassium carbonate solution (2M, 4 mL), and toluene (20 mL) were added to a three-necked flask under the protection of nitrogen. After repeating vacuuming and nitrogen introduction three times, the reaction mixture was heated to reflux and stirred overnight. After cooling to room temperature, the mixture was extracted with ethyl acetate. The organic phase was washed with a saturated saline solution for three times, dried over anhydrous sodium sulfate, and then subjected to an evaporation under reduced pressure to remove the solvent. The residue was subjected to a separation by silica gel column chromatography to obtain 0.92 g of a pale yellow solid with a yield of 53%. ESI-MS (m z): 601.33 (M+1).

### Synthesis of Complex 61

In a 250 mL of single-necked flask, 61b (0.85 g, 1.41 mmol), potassium tetrachloroplatinate (0.70 g, 1.69 mmol), and tetrabutylammonium bromide (50 mg) were dissolved in acetic acid (150 mL), and subjected to a rection under stirring and the protection of nitrogen at 135° C. for 24 hours. After cooling to room temperature, the reaction liquid was added with water to precipitate a solid, and filtered to obtain a crude product. The crude product was recrystallized in dichloromethane/n-hexane (1/1) to obtain 0.56 g of orange red powder with a yield of 50%. ESI-HRMS (m z): 794.2826 (M+1).

### Example 5: Synthesis of Complex 72

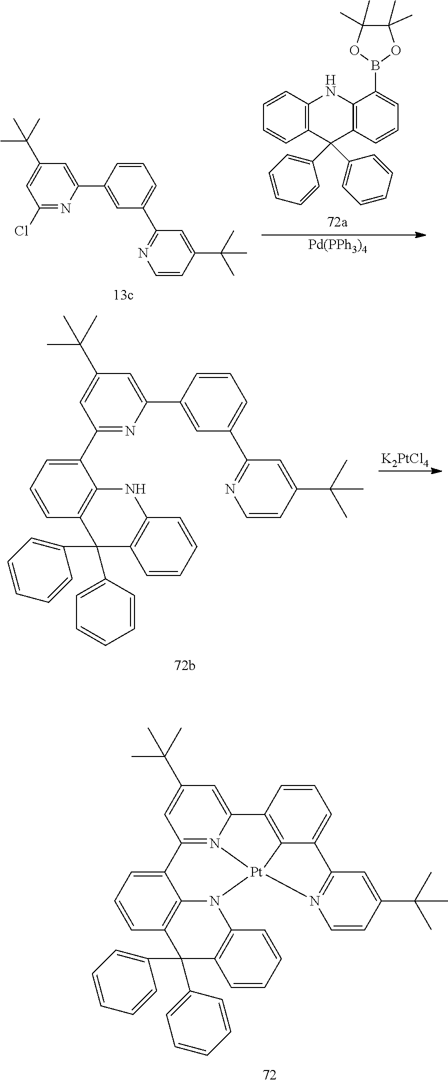

### Synthesis of Compound 72b

13c (1.10 g, 2.90 mmol), 72a (synthesized with reference to patent KR20200109533A, 1.60 g, 3.48 mmol), tetrakis(triphenylphosphine) palladium (0.17 g, 0.15 mmol), potassium carbonate solution (2M, 4 mL), and toluene (20 mL) were added to a three-necked flask under the protection of nitrogen. After repeating vacuuming and nitrogen introduction three times, the reaction mixture was heated to reflux and stirred overnight. After cooling to room temperature, the mixture was extracted with ethyl acetate. The organic phase was washed with a saturated saline solution for three times, dried over anhydrous sodium sulfate, and then subjected to an evaporation under reduced pressure to remove the solvent. The residue was subjected to a separation by silica gel column chromatography to obtain 0.82 g of a pale yellow solid with a yield of 42%. ESI-MS (m z): 676.37 (M+1).

### Synthesis of Complex 72

In a 250 mL of single-necked flask, 72b (0.70 g, 1.04 mmol), potassium tetrachloroplatinate (0.52 g, 1.25 mmol), and tetrabutylammonium bromide (50 mg) were dissolved in acetic acid (100 mL), and subjected to a rection under stirring and the protection of nitrogen at 135° C. for 24 hours. After cooling to room temperature, the reaction liquid was added with water to precipitate a solid, and filtered to obtain a crude product. The crude product was recrystallized in dichloromethane/n-hexane (1/1) to obtain 0.39 g of orange red powder with a yield of 43%. ESI-HRMS (m z): 869.3186 (M+1).

Those skilled in the art should be understood that the above preparation methods are only several exemplary examples, and modifications can be made on them by those skilled in the art to obtain the structures of other compounds in the present application.

### Example 6

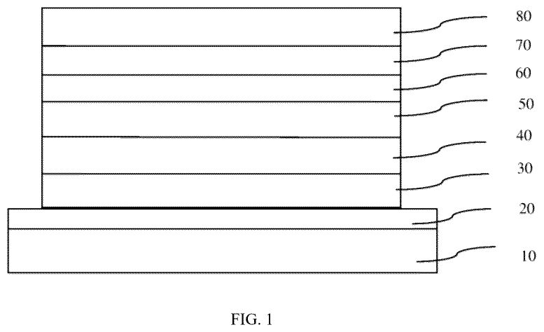

An organic light-emitting diode was prepared using the complex luminescent material of the present application, and the structure of the device is as shown in FIG. 1.

Firstly, a transparent conductive ITO glass substrate 10 (provided with an anode 20 thereon) was washed sequentially with a detergent solution and deionized water, ethanol, acetone, and deionized water, and then treated with oxygen plasma for 30 seconds.

Then, HATCN was evaporated onto ITO as a hole injection layer 30 with a thickness of 10 nm.

Then, the compound HT was evaporated to form a hole transport layer 40 with a thickness of 40 nm.

Then, a light-emitting layer 50 with a thickness of 20 nm was evaporated onto the hole transport layer. The light-emitting layer was formed of the platinum complex 13 (20%) in combination with CBP (80%).

Then, AlQ₃ was evaporated onto the light-emitting layer as an electron transport layer 60 with a thickness of 40 nm.

Finally, 1 nm LiF was evaporated as an electron injection layer 70 and 100 nm Al was evaporated as a cathode 80 of the device.

Example 7: An organic light-emitting diode was prepared by the method as described in Example 6, with the complex 13 replaced by the complex 33.

Example 8: An organic light-emitting diode was prepared by the method as described in Example 6, with the complex 13 replaced by the complex 49.

Example 9: An organic light-emitting diode was prepared by the method as described in Example 6, with the complex 13 replaced by the complex 61.

Example 10: An organic light-emitting diode was prepared by the method as described in Example 6, with the complex 13 replaced by the complex 72.

### Comparative Example 1

An organic light-emitting diode was prepared by the method as described in Example 6, with the complex 13 replaced by a complex Ref-1 (U.S. Pat. No. 10,566,566B2).

The structural formulas of HATCN, HT, AlQ₃, Ref-1, and RH in the device are as follows:

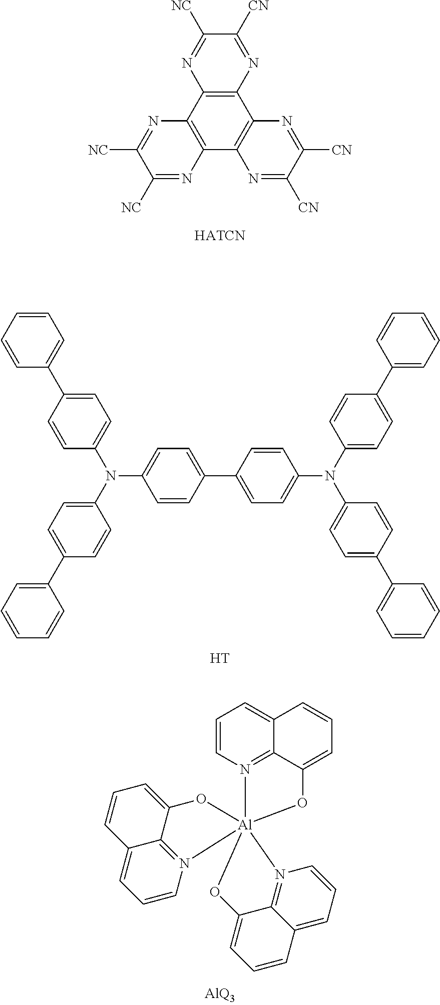

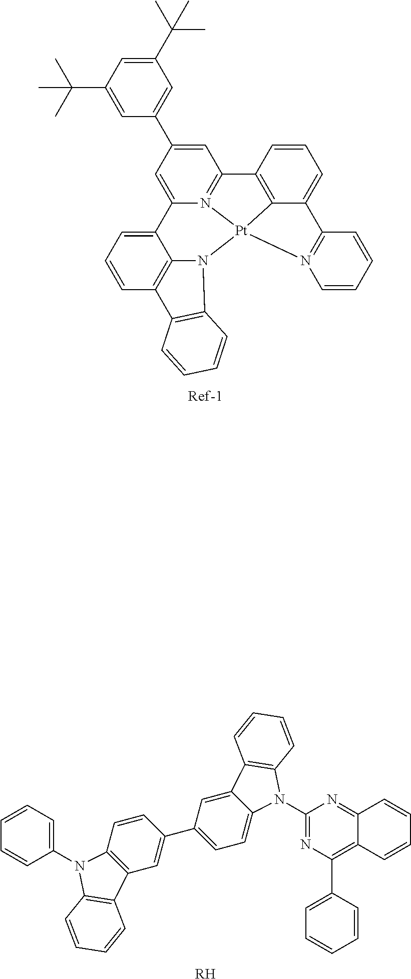

The device performances of the organic electroluminescent devices in Examples 6-10 and Comparative example 1 at a current density of 10 mA/cm² are listed in Table 1:

TABLE 1

| | | | | | Service |
|---|---|---|---|---|---|
| | | | | | life of |
| | | Driving | Luminous | Emitted | device |
| Device No. | Complex | voltage | efficiency | color | (LT98) |
| Example 6 | Complex 13 | 0.95 | 1.15 | Dark red | 1.52 |
| Example 7 | Complex 33 | 0.95 | 1.09 | Dark red | 1.26 |
| Example 8 | Complex 49 | 0.97 | 1.10 | Dark red | 1.21 |
| Example 9 | Complex 61 | 0.97 | 0.98 | Dark red | 1.66 |
| Example 10 | Complex 72 | 0.95 | 1.15 | Dark red | 2.10 |
| Comparative | Ref-1 | 1 | 1 | Orange | 1 |
| example 1 | | | | red | |

Note:
The properties of the device were tested with Comparative Example 1 as a benchmark, with individual indicators of properties of the device in Comparative Example 1 as 1. LT98 refers to a duration until the device's brightness diminishes to 98% of the initial brightness (10000 cd/m²).

From the data shown in Table 1, it can be seen that under the same condition, the platinum complex materials of the present application can be used to prepare the organic light-emitting diodes emitting deep red lights, with lower driving voltages and higher luminous efficiencies. In addition, the device service lives of the organic light-emitting diode based on the complexes of the present application are significantly longer as compared to the complex materials in the Comparative Example, meeting the requirements on the luminescent materials in the display industry and having good industrialization prospects.

The various embodiments as described above are only used as examples, and are not intended to limit the scope of the present application. Other materials and structures may be used to replace the various materials and structures in the present application without departing from the spirit of the present application. It should be understood that various modifications and changes may be made by those skilled in the art according to the concept of the present application without creative effort. Therefore, all technical solutions obtained by those skilled in the art through analysis, inference, or partial research on basis of the existing technologies shall fall within the scope of protection defined by the claims.

1. A NNCN tetradentate ligand-containing platinum complex, being a compound having a structure of formula (I): 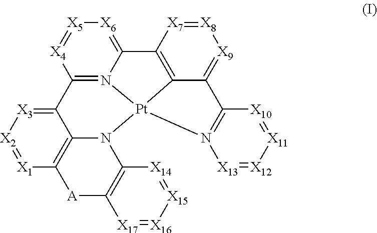
wherein:
X₁ to X₁₇ are each independently selected from the group consisting of N and CR;
A is selected from the group consisting of CR¹R², NR³, O, S, and Se;
R, R¹, R², and R³ are each independently selected from the group consisting of hydrogen, deuterium, halogen, amino, carbonyl, carboxyl, thioalkyl, cyano, sulfonyl, phosphino, a substituted or unsubstituted alkyl having 1 to 20 carbon atoms, a substituted or unsubstituted cycloalkyl having 3 to 20 ring carbon atoms, a substituted or unsubstituted alkenyl having 2 to 20 carbon atoms, a substituted or unsubstituted alkoxy having 1 to 20 carbon atoms, a substituted or unsubstituted aryl having 6 to 30 carbon atoms, a substituted or unsubstituted heteroaryl having 3 to 30 carbon atoms, and a combination thereof, or any two adjacent substituents can be optionally linked to form a ring;
a heteroatom in the heteroaryl includes one or more of N, S, or O;
the “substituted” refers to substitution with halogen, amino, cyano, or C1-C4 alkyl.

2. The platinum complex of claim 1, wherein R, R¹, R², and R³ are each independently selected from the group consisting of hydrogen, deuterium, halogen, amino, thioalkyl, cyano, a substituted or unsubstituted alkyl having 1 to 6 carbon atoms, a substituted or unsubstituted cycloalkyl having 3 to 6 ring carbon atoms, a substituted or unsubstituted alkenyl having 2 to 6 carbon atoms, a substituted or unsubstituted alkoxy having 1 to 6 carbon atoms, a substituted or unsubstituted aryl having 6 to 12 carbon atoms, and a substituted or unsubstituted heteroaryl having 3 to 6 carbon atoms, and A is selected from the group consisting of CR¹R², NR³, O, and S.

3. The platinum complex of claim 2, having the following structure: 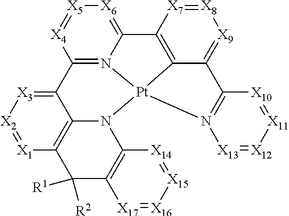
wherein R, R¹, and R² are each independently selected from the group consisting of hydrogen, deuterium, methyl, tert-butyl, a substituted or unsubstituted cyclopentyl, a substituted or unsubstituted cyclohexyl, a substituted or unsubstituted phenyl, and a substituted or unsubstituted pyridyl.

4. The platinum complex of claim 1, wherein X₁ to X₁₇ are each independently selected from CR.

5. The platinum complex of claim 4, wherein X₁ to X₃ and X₁₄ to X₁₇ are CH.

6. The platinum complex of claim 5, wherein at least one of X₄ to X₆ is not CH; at least one of X₇ to X₉ is not CH, and at least one of X₁₀ to X₁₃ is not CH.

7. The platinum complex of claim 6, wherein X₅ in X₄ to X₆ is not CH, X₈ in X₇ to X₉ is not CH, X₁₁ in X₁₀ to X₁₃ is not CH, and the rest are CH.

8. The platinum complex of claim 5, wherein at least one of X₄ to X₆ is not CH; X₇ to X₉ each are CH, and at least one of X₁₀ to X₁₃ is not CH.

9. The platinum complex of claim 8, wherein X₅ in X₄ to X₆ is not CH, X₁₁ in X₁₀ to X₁₃ is not CH, and the rest are CH.

10. The platinum complex of claim 1, being one of the following compounds:

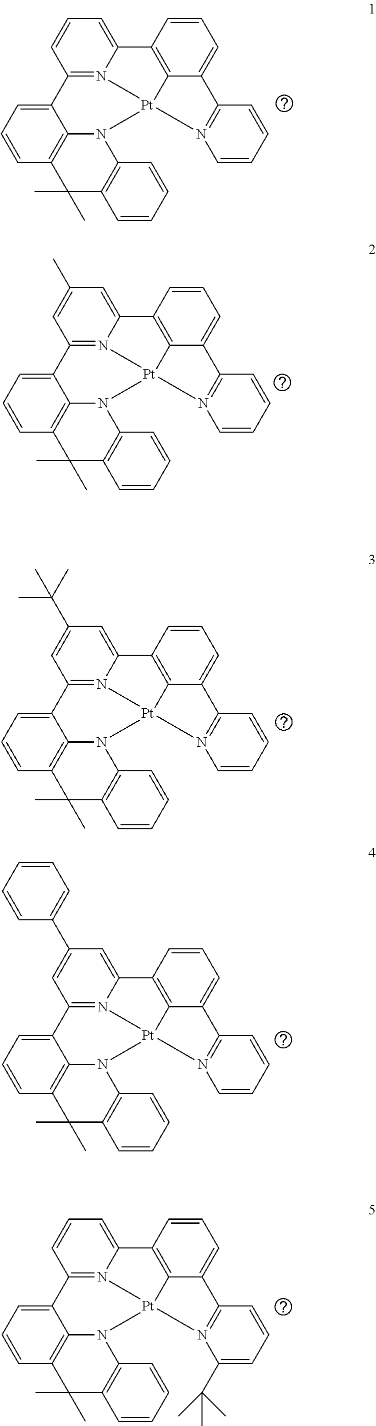

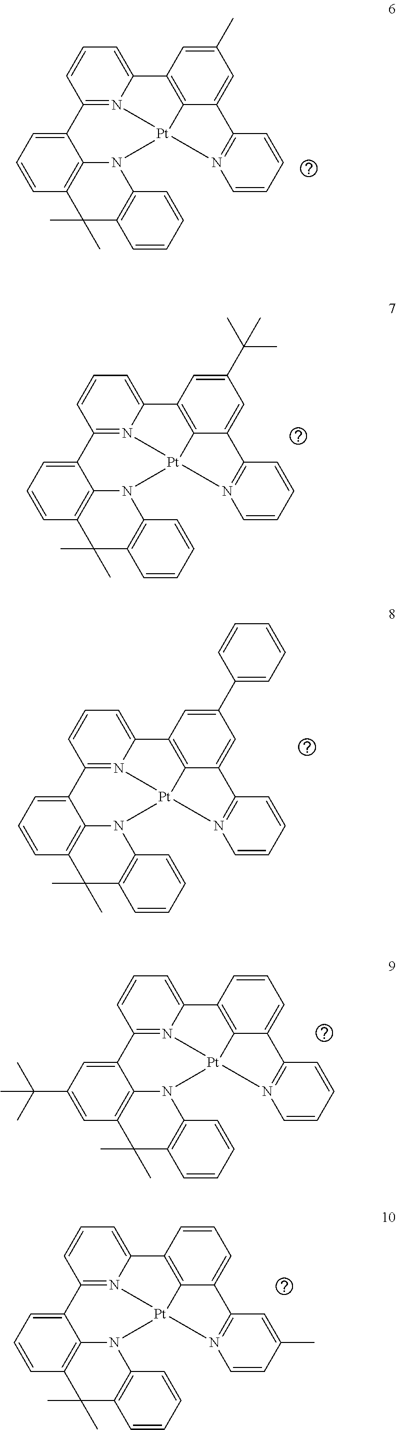

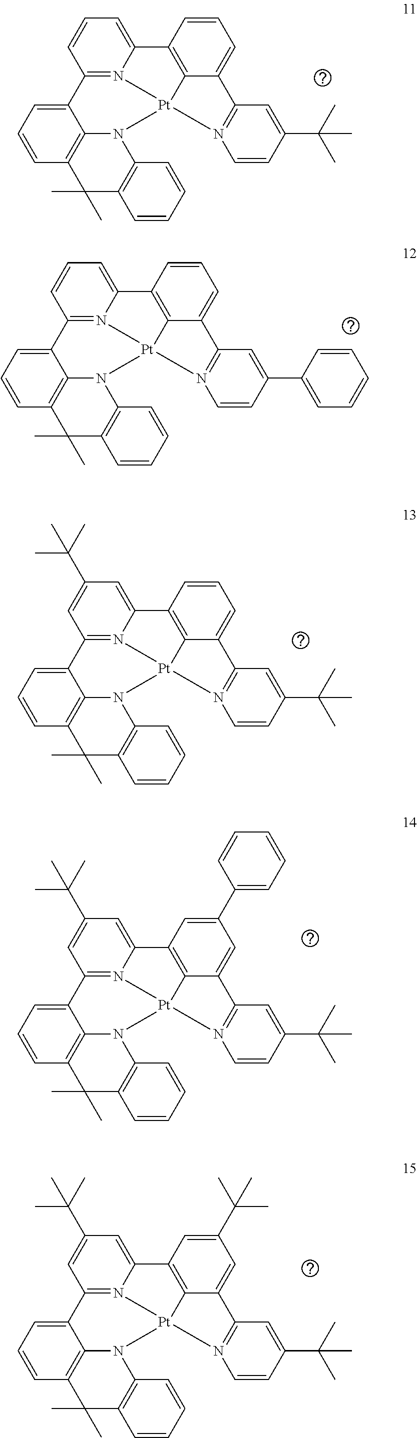

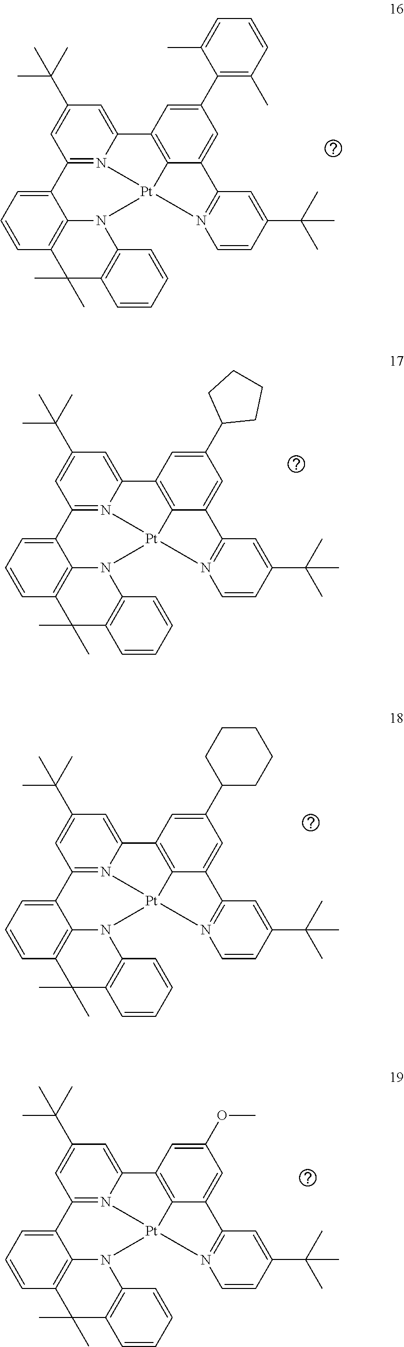

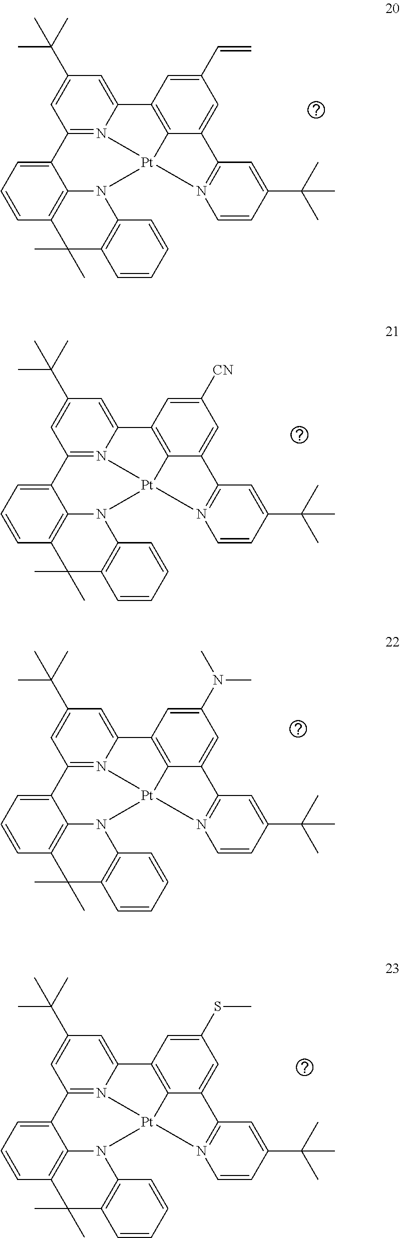

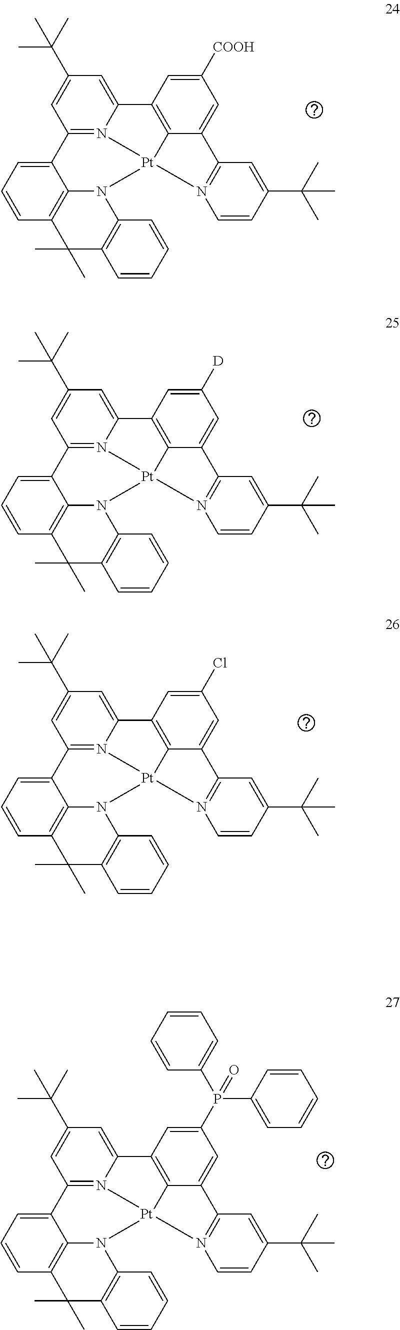

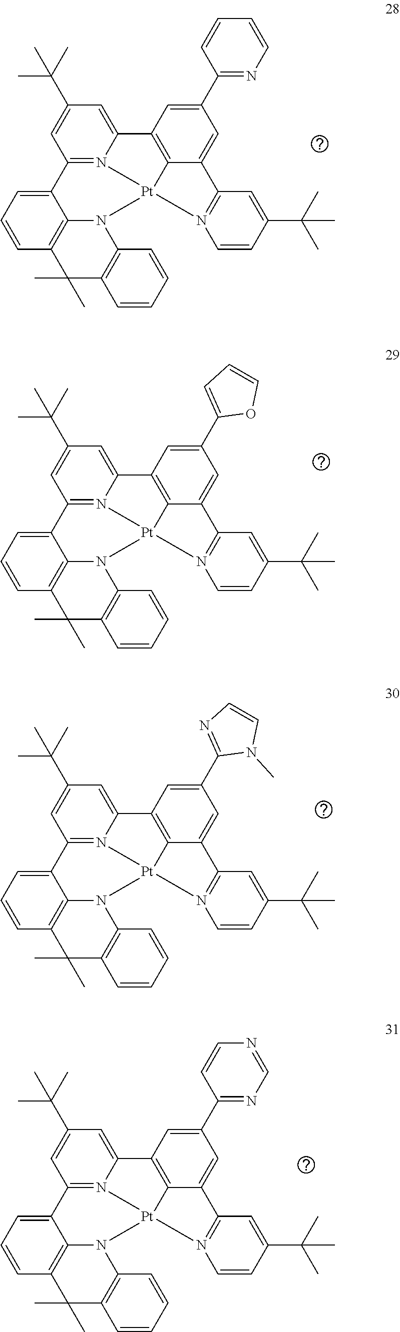

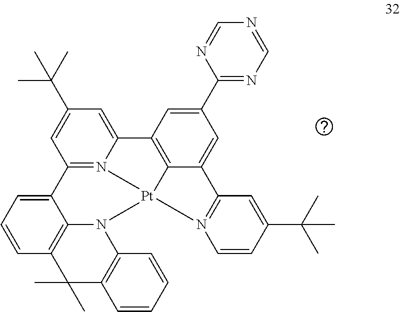

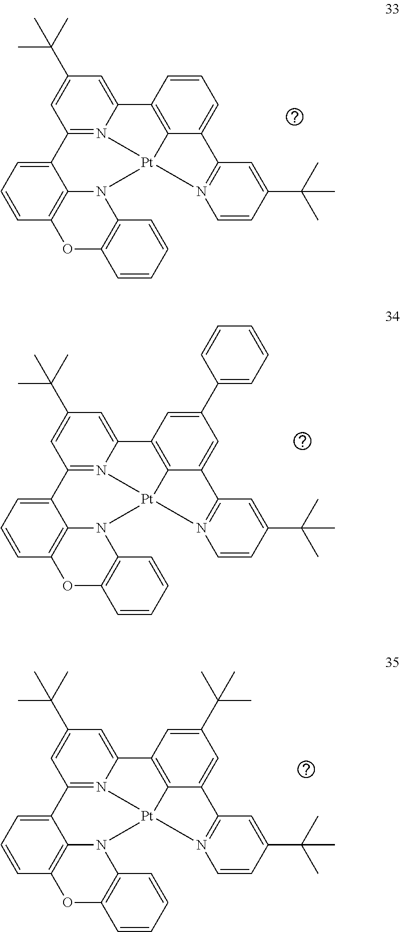

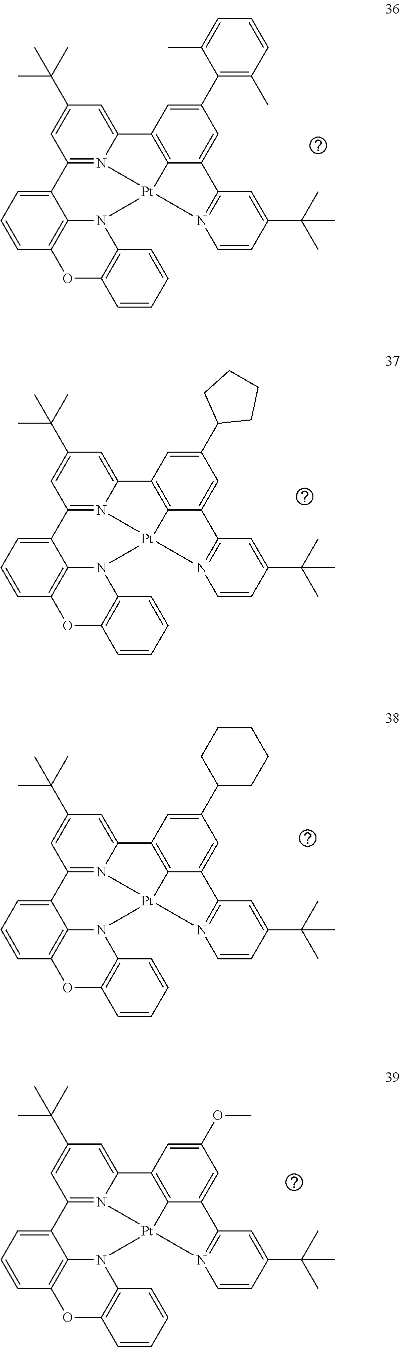

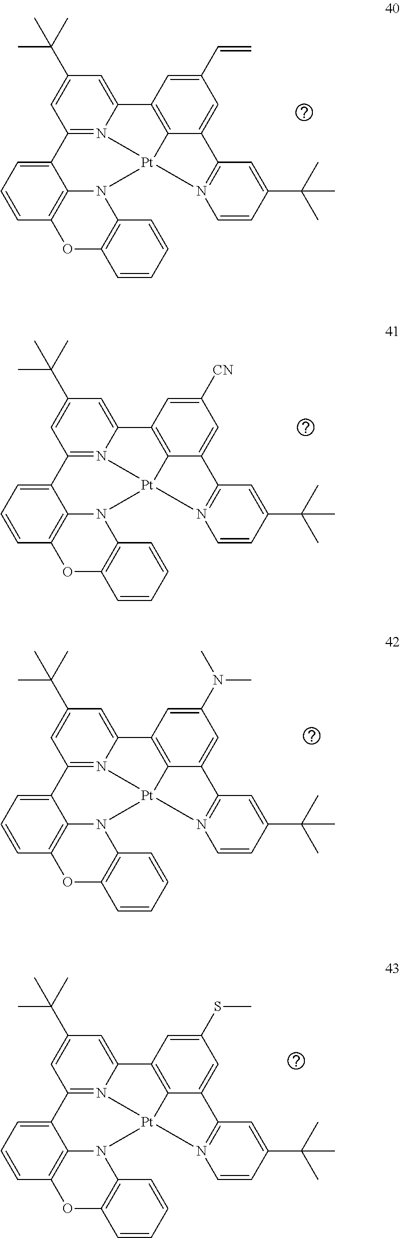

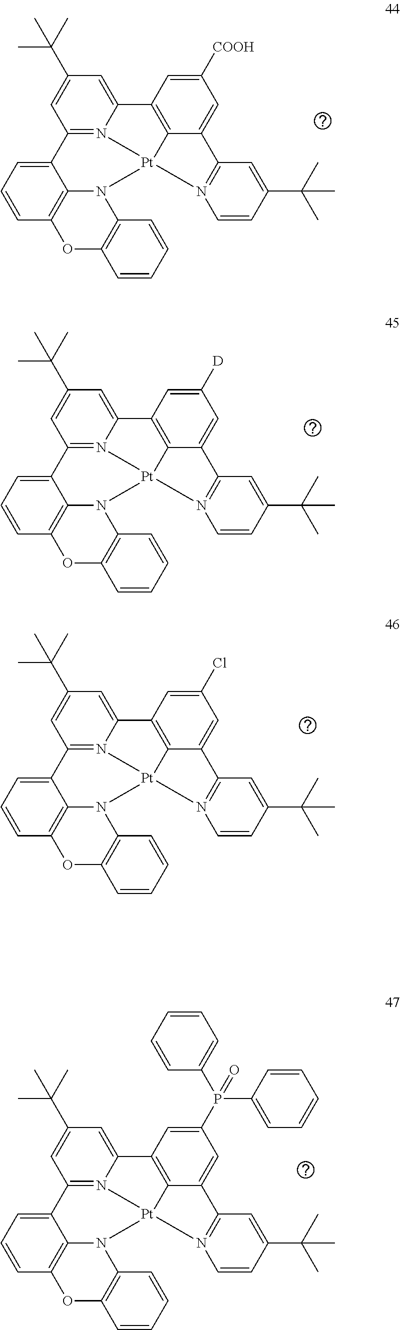

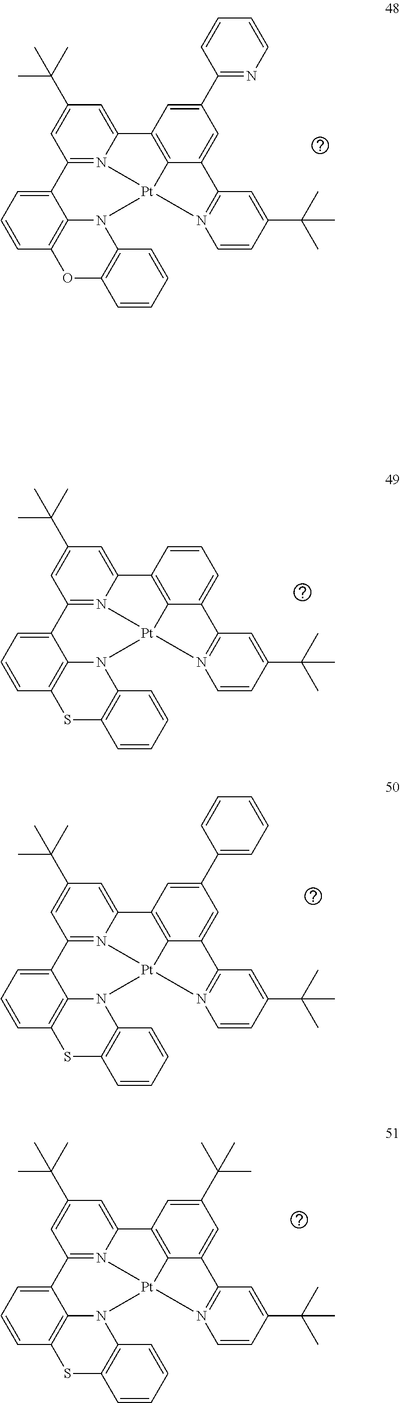

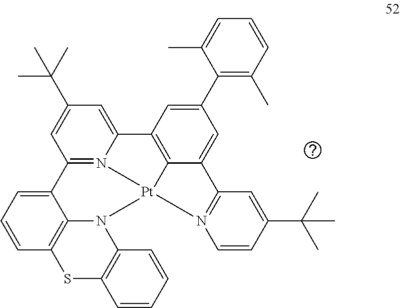

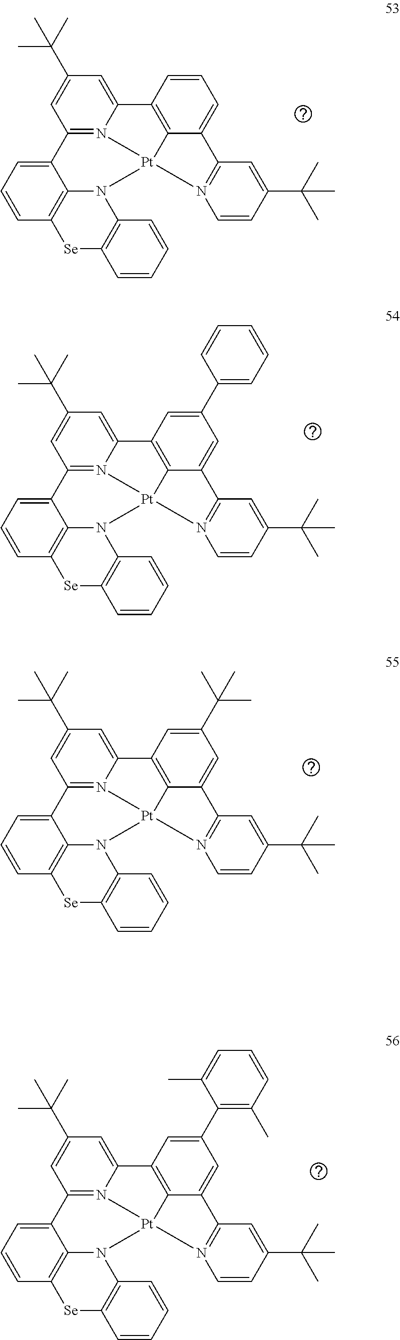

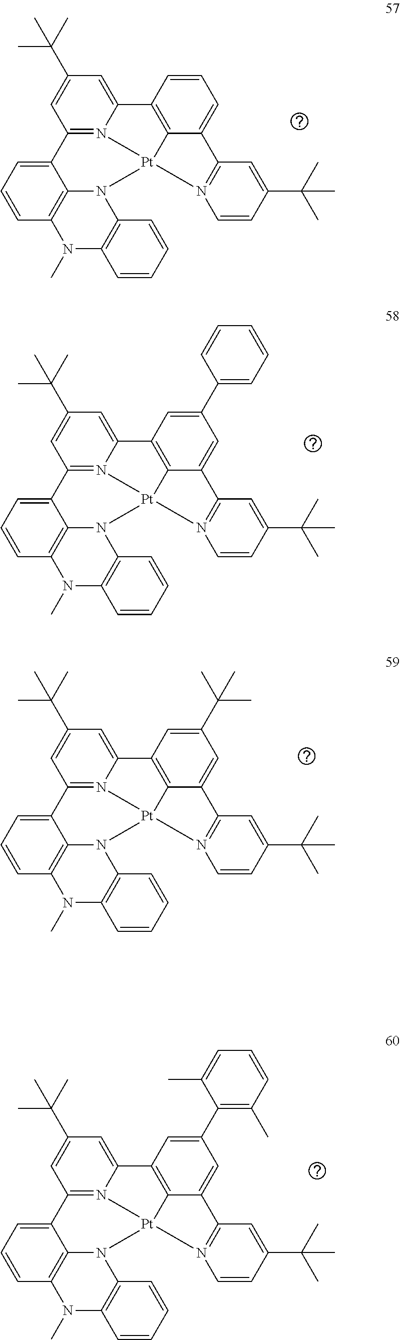

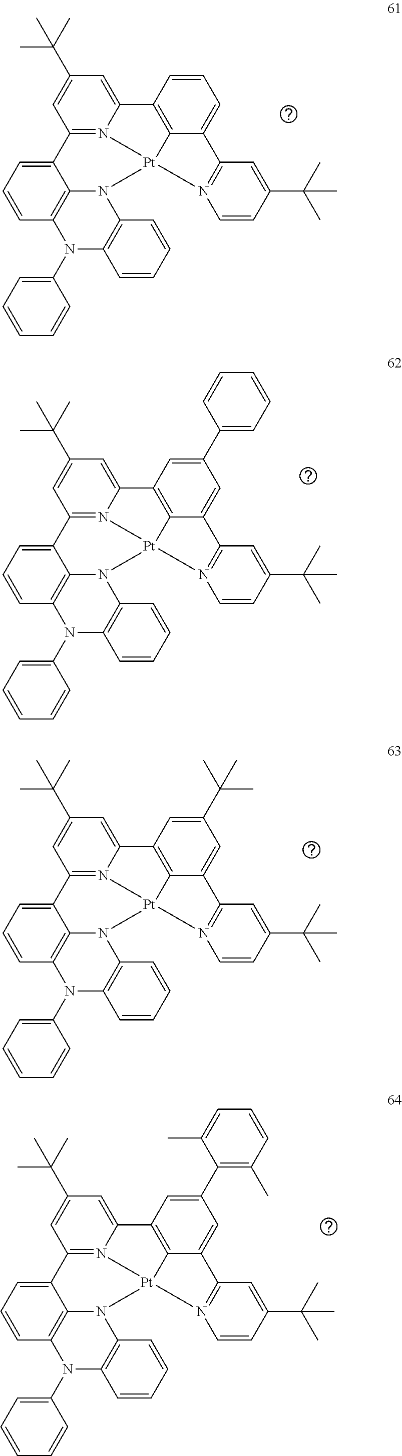

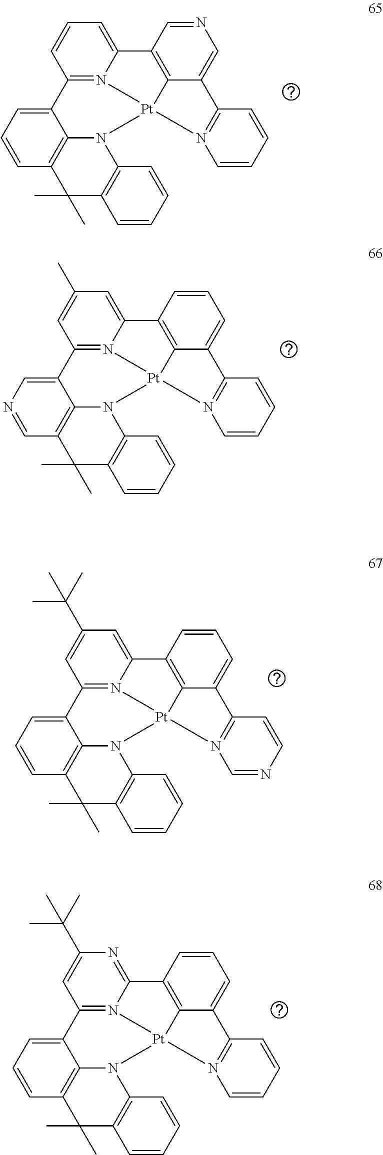

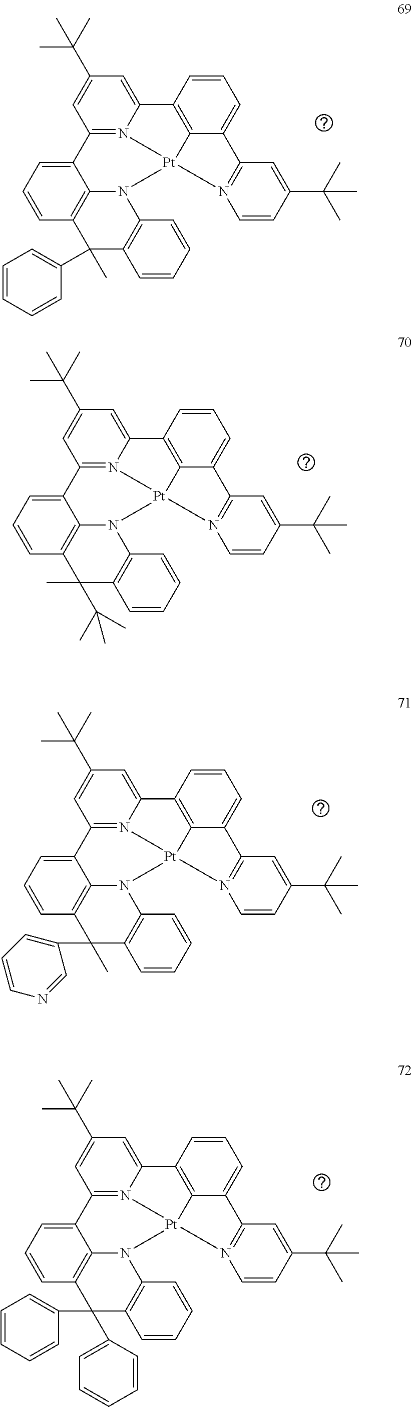

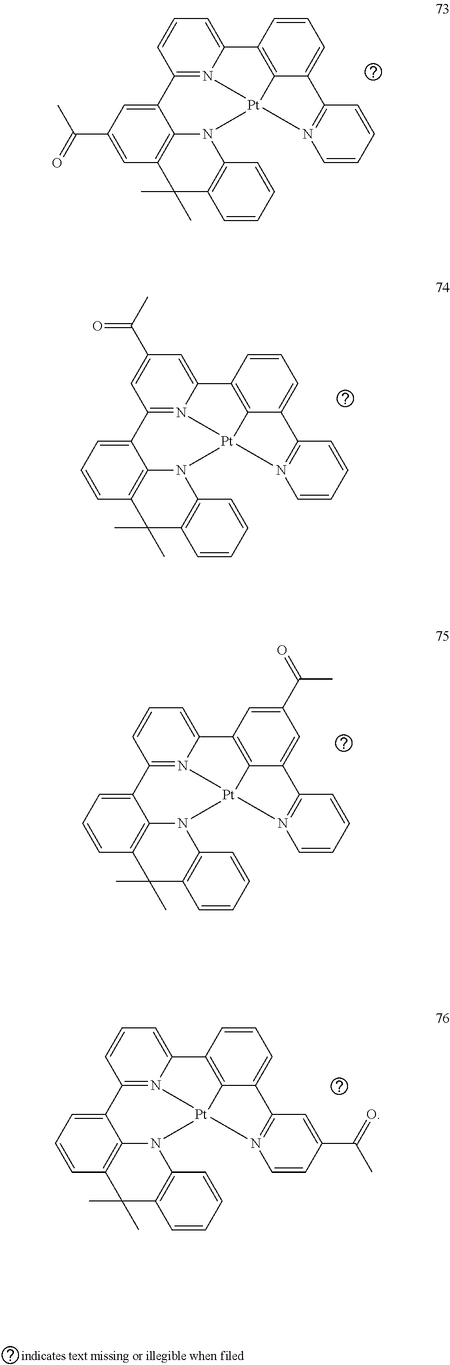

11. A precursor or a ligand, of the platinum complex of claim 1, having the following structural formula:

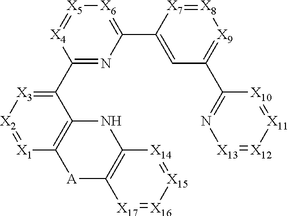

12. A device, comprising: the platinum complex of claim 1, wherein the device is in an organic light-emitting diode, an organic thin film transistor, an organic photovoltaic device, a luminescent electrochemical cell, or a chemical sensor.

13. An organic light-emitting diode, comprising a cathode, an anode, and an organic layer, wherein the organic layer comprises one or more of a hole injection layer, a hole transport layer, a light-emitting layer, a hole blocking layer, an electron injection layer, or an electron transport layer, and the organic layer contains the platinum complex of claim 1.

14. The organic light-emitting diode of claim 13, wherein the light-emitting layer contains the platinum complex.
